(19) United States
(12) Patent Application Publication
(10) Pub. No.: US 2007/0030065 A1
(43) Pub. Date: Feb. 8, 2007

(54) Data processing method, pre-distortion arrangement, transmitter, network element and base station

(75) Inventors: Kauko Heinikoski, Oulu (FI); Samu Saarinen, Oulu (FI); Pekka Kukkonen, Oulu (FI)

Correspondence Address: SQUIRE, SANDERS & DEMPSEY L.L.P., 14TH FLOOR, 8000 TOWERS CRESCENT, TYSONS CORNER, VA, 22182, US

(73) Assignee: Nokia Corporation

(21) Appl. No.: 11/476,761

(22) Filed: Jun. 29, 2006

(30) Foreign Application Priority Data
Jun. 29, 2005 (FI) 20055355

(51) Int. Cl. H03F 1/26

(52) U.S. Cl. 330/149

(57) ABSTRACT

A transmitter includes generating unit configured to generate a feedback signal and an analyzing unit configured to analyze transmission quality in a time domain and in a frequency domain by using the feedback signal. The transmitter also includes an adapting unit configured to adapt the pre-distorter if the transmission quality is below the threshold.

### FIELD

The invention relates to a data processing method in a transmitter, the transmitter comprising a pre-distorter, a pre-distortion arrangement, a transmitter, a network element and a base station.

### BACKGROUND

Due to non-linear effects of analog components of a transmission chain, a transmitted signal is distorted in amplitude and phase. The main cause for such distortions is a power amplifier of a transmitter. In addition to amplifying a desired signal, the power amplifier generates higher order harmonics of the original signal spectrum. The spread of the signal spectrum causes two major effects: a radio frequency spectrum mask does not fulfil the requirements for out-of-band radiated power, and detection of a distorted signal in a receiver suffers from errors.

The spread of the signal spectrum can be avoided (or at least reduced) by using a linearization technique. Several different prior art linearization techniques exist. The most effective of them are adaptive, since a plurality of factors, such as temperature, affect a transmission chain, making it unstable.

Linearization is usually implemented by using a pre-distorter which is adaptable on the basis of a feedback signal from the output of a power amplifier. The problem is that adaptation requires quite large amount of computational resources. Therefore, avoiding unnecessary adaptation may reduce processor load remarkably.

### BRIEF DESCRIPTION OF THE INVENTION

According to an aspect of the invention, there is provided a data processing method, the method comprising: generating a feedback signal; analysing transmission quality by using the feedback signal; and adapting the pre-distorter of a transmitter on the basis of results of the analysis.

According to an aspect of the invention, there is provided a data processing method, the method comprising: setting a threshold for transmission quality; generating a feedback signal; analysing transmission quality in a time domain and in a frequency domain by using the feedback signal; and adapting the pre-distorter of a transmitter if the transmission quality is below the threshold.

According to another aspect of the invention, there is provided a pre-distortion arrangement, comprising: generating unit configured to generate a feedback signal; analysing unit configured to analyze transmission quality by using the feedback signal; adapting unit configured to adapt the pre-distorter on the basis of results of the analysis of the analyzing unit.

According to another aspect of the invention, there is provided a pre-distortion arrangement, comprising: generating unit configured to generate a feedback signal; analysing unit configured to analyze transmission quality in a time domain and in a frequency domain by using the feedback signal; and adapting unit configured to adapt the pre-distorter if the transmission quality is below the threshold.

According to another aspect of the invention, there is provided a transmitter, comprising: generating unit configured to generate a feedback signal; analysing unit configured to analyze transmission quality by using the feedback signal; and adapting unit configured to adapt the pre-distorter on the basis of results of the analysis of the analyzing unit.

According to another aspect of the invention, there is provided a transmitter, comprising: generating unit configured to generate a feedback signal; analysing unit configured to analyze transmission quality in a time domain and in a frequency domain by using the feedback signal; and adapting unit configured to adapt the pre-distorter if the transmission quality is below the threshold.

According to another aspect of the invention, there is provided a network element, comprising: generating unit configured to generate a feedback signal; analysing unit configured to analyze transmission quality by using the feedback signal; and adapting unit configured to adapt the pre-distorter on the basis of results of the analysis of the analyzing unit.

According to another aspect of the invention, there is provided a network element, comprising: generating unit configured to generate a feedback signal; analysing unit configured to analyze transmission quality in a time domain and in a frequency domain by using the feedback signal; and adapting unit configured to adapt the pre-distorter if the transmission quality is below the threshold.

According to another aspect of the invention, there is provided a base station comprising: generating unit configured to generate a feedback signal; analysing unit configured to analyze transmission quality by using the feedback signal; and adapting unit configured to adapt the pre-distorter on the basis of results of the analysis of the analyzing unit.

According to another aspect of the invention, there is provided a base station comprising: generating unit configured to generate a feedback signal; analysing unit configured to analyze transmission quality in a time domain and in a frequency domain by using the feedback signal; and adapting unit configured to adapt the pre-distorter if the transmission quality is below the threshold.

According to another aspect of the invention, there is provided a pre-distortion arrangement, configured to: generate a feedback signal; analyse transmission quality by using the feedback signal; and adapt the pre-distorter on the basis of results of the analysis.

According to another aspect of the invention, there is provided a pre-distortion arrangement, configured to: generate a feedback signal; analyse transmission quality in a time domain and in a frequency domain by using the feedback signal; and adapt the pre-distorter if the transmission quality is below the threshold.

According to another aspect of the invention, there is provided a transmitter, configured to: generate a feedback signal; analyse transmission quality by using the feedback signal; and adapt the pre-distorter on the basis of results of the analysis

According to another aspect of the invention, there is provided a transmitter, configured to: generate a feedback signal; analyse transmission quality in a time domain and in a frequency domain by using the feedback signal; and adapt the pre-distorter if the transmission quality is below the threshold.

According to another aspect of the invention, there is provided a network element, configured to: generate a feedback signal; analyse transmission quality by using the feedback signal; and adapt the pre-distorter on the basis of results of the analysis.

According to another aspect of the invention, there is provided a network element, configured to: generate a feedback signal; analyse transmission quality in a time domain and in a frequency domain by using the feedback signal; and adapt the pre-distorter if the transmission quality is below the threshold.

According to another aspect of the invention, there is provided a base station configured to: generate a feedback signal; analyse transmission quality by using the feedback signal; and adapt the pre-distorter on the basis of results of the analysis.

According to another aspect of the invention, there is provided a base station configured to: generate a feedback signal; analyse transmission quality in a time domain and in a frequency domain by using the feedback signal; and adapt the pre-distorter if the transmission quality is below the threshold.

The invention provides several advantages.

In an embodiment of the invention, the operation of a pre-distorter can be controlled on the basis of transmission quality determined from a feedback signal. In the embodiment, processor load can be diminished, since the pre-distorter is adapted only when required. If the transmission quality is adequate, pre-distorter parameters are kept unchanged. Another advantage is that the embodiment provides an option to control that the pre-distorter converges in the right direction.

### LIST OF DRAWINGS

In the following, the invention will be described in greater detail with reference to the embodiments and the accompanying drawings, in which

FIG. 1 shows an example of a communication system;

FIG. 2 is a flow chart;

FIG. 3 illustrates an example of a pre-distorter; and

FIG. 4 illustrates an example of a transmitter.

### DESCRIPTION OF EMBODIMENTS

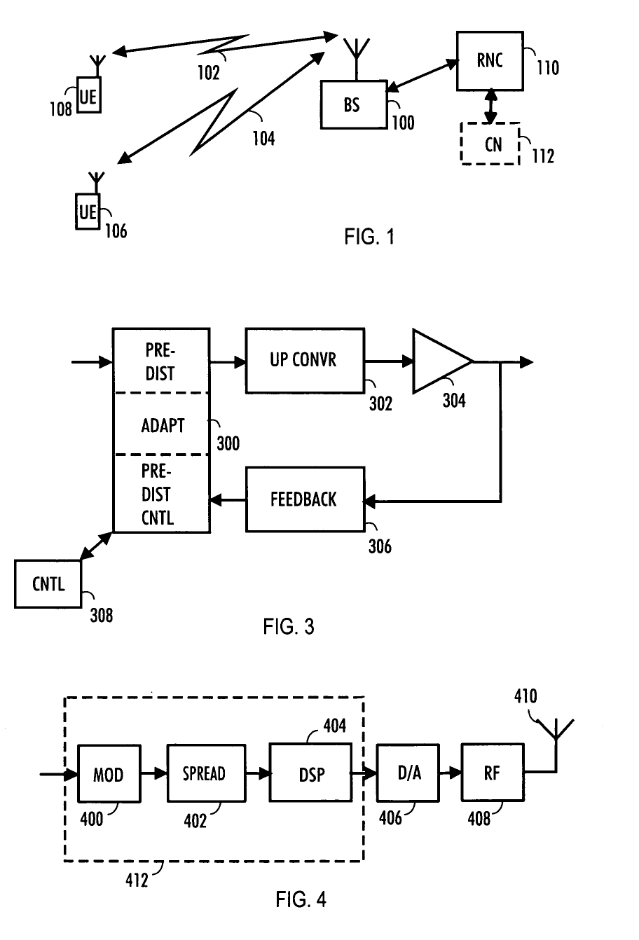

With reference to FIG. 1, we examine an example of a communication system to which embodiments of the invention can be applied. The present invention can be applied to various communication systems. One example of such a communication system is a Universal Mobile Telecommunications System (UMTS) radio access network (UTRAN). It is a radio access network which includes wideband code division multiple access (WCDMA) technology and can also offer real-time circuit and packet switched services. The embodiments are not, however, restricted to the systems given as examples but a person skilled in the art may apply the solution to other communication systems provided with the necessary properties.

It is clear to a person skilled in the art that the method according to the invention can be applied to systems utilizing different modulation methods or air interface standards.

FIG. 1 is a simplified illustration of a part of a digital data transmission system to which the solution according to the invention is applicable. This is a part of a cellular radio system, which comprises a base station (or node B) 100, which has bi-directional radio links 102 and 104 to user terminals 106 and 108. The user terminals may be fixed, vehicle-mounted or portable. The base station includes transceivers, for instance. From the transceivers of the base station, there is a connection to an antenna unit that establishes the bi-directional radio links to the user terminal. The base station is further connected to a controller 110, such as a radio network controller (RNC), which transmits the connections of the terminals to the other parts of the network. The radio network controller controls in a centralized manner several base stations connected to it. The radio network controller is further connected to a core network 112 (CN). Depending on the system, the counterpart on the CN side can be a mobile services switching centre (MSC), a media gateway (MGW) or a serving GPRS (general packet radio service) support node (SGSN).

The radio system can also communicate with other networks, such as a public switched telephone network or the Internet.

The size of communication systems can vary according to the data transfer needs and to the required coverage area.

First, the principle of pre-distortion is clarified.

The main cause for distortions is non-linearity of a power amplifier. Power amplifiers are required in radio systems to amplify signals before transmission, because radio signals attenuate on the radio path. Unfortunately, high-power radio-frequency amplifiers tend to be non-linear devices and therefore they often cause distortion. This distortion is expressed, for example, as Inter-Symbol-Interference or out-off-band power in adjacent frequency bands. An ACLR (Adjacent Carrier Leakage Ratio) quantifies the out-off-band transmitted power and thus it must remain within specified limits.

Linear amplification is mostly needed when the transmitted signal contains both amplitude and phase modulation. Examples of these modulation methods include quadrature phase-shift keying (QPSK) and orthogonal frequency division multiplexing (OFDM).

Pre-distortion generates a non-linear transfer function which can be thought of as a reverse of the power amplifier's transfer function taking into account both amplitude and phase. In other words, pre-distortion is designed to provide distortion complementary to that of the power amplifier, prior to the input of the power amplifier, producing an overall linear transfer function.

Effective pre-distortion requires adaptation since changes in parameters, such as in signal phase, modulation, component characteristics or temperature, change the transfer function of the power amplifier. For the adaptation, feedback from the power amplifier's output signal is required. The feedback is usually generated by using a feedback chain to produce measurement results from the power amplifier's output signal.

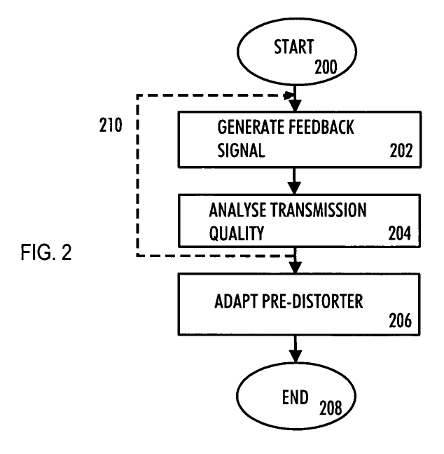

Next, an embodiment of the data processing method in a transmitter is explained by means of FIG. 2. The embodiment may be carried out in the pre-distortion arrangement of FIG. 3. A plurality of different prior art adaptive pre-distortion methods exist, but they are not clarified here in further detail. There is no limitation to the selection of an adaptive pre-distortion method to be used with the embodiment as far as information on the transmission quality is available.

The embodiment starts is block 200.

In block 202, a feedback signal is generated. The feedback signal may be generated by using a feedback chain. Next, a part of the output signal of the power amplifier is taken into the feedback chain for generating a feedback signal.

In block 204, transmission quality is analysed by using the feedback signal. The transmission quality is typically analysed both in the time domain and in the frequency domain. The analyses can be carried out by comparing the selected parameters of the feedback signal to one or more pre-determined threshold values. Threshold values may be determined on the basis of experience or simulations.

Several prior art analysing methods are used in 3GPP (3^{rd} Generation Partnership Project) systems and some of them are now briefly clarified.

An error Vector Magnitude (EVM) is a measure for a difference between a reference waveform and a measured waveform. The difference is called an error vector. The EVM result is defined as the square root of the ratio of a mean error vector power to a mean reference power expressed as percentages. The EVM is an indicator of the quality of modulation.

Adjacent Channel Leakage Ratio (ACRL) indicates the ratio of channel transmit power to power on one of the adjacent channels. ACRL estimation is used for measuring intermodulation distortion caused by a power amplifier.

A spectrum Emission Mask (SEM) specifies a limit for out-of-band emissions, caused by modulation, transmitter non-linearity and/or spurious emissions. Attention should be paid to the fact that some limitations exist to the reliability of SEM estimation when the estimation is made from a feedback signal.

The analysing methods are explained in 3 GPP specifications in greater detail.

Other prior art options also exist to obtain information on the transmission quality, such as determination of direct current offset (DC off-set), signal amplitudes, Crest Factor (CF) or Complementary Cumulative Distribution Function CCDF.

Transmission quality can be analysed during a transmission continuously or periodically, in other words, a quality analysis can be repeated as depicted by arrow 210. The quality analysis can be carried out in order to track whether a pre-distorter converges in the right direction.

In block 206, the pre-distorter is adapted on the basis of the results of the analyses. Typically, the pre-distorter is adapted if the analysed character does not fulfil the criteria set by means of a threshold. For instance, if an Error Vector Magnitude or an Adjacent Channel Leakage Ratio is too large, adaptation of suitable parameters is triggered in order to improve the transmission quality or system performance.

It is further possible to set a control to ensure that the adaptation process stops after the upper limit for adaptation rounds has been reached. The adaptation may be restarted after a period of time. In FIG. 2, only one full round has been illustrated.

The embodiment ends in block 208.

Next, an example of a pre-distortion arrangement is explained by means of FIG. 3. In the example, the pre-distortion arrangement includes a feedback chain 306, a digital adaptive pre-distorter (DAPD) 300, and a transmitter controller 308.

The transmitter chain in FIG. 3 includes up-conversion block 302 which carries out, for instance, digital-to-analog conversion. The transmitter chain is depicted here only for the sake of clarity.

In the embodiment, the feedback chain includes down-conversion to a base band frequency, analog-to-digital conversion and other signal process steps necessary for returning the output signal of power amplifier 304 to a form suitable for digital processing.

The digital adaptive pre-distorter includes control functions for controlling the pre-distorter, pre-distortion adaptation and the actual pre-distortion.

The pre-distortion adaptation is typically carried out by changing selected parameters of one or more pre-distortion algorithms. The pre-distortion, in turn, is typically carried out by modifying a signal with selected pre-distortion algorithms. The purpose is to compensate for unwanted phase and amplitude changes caused by the transmission chain in the signal to be transmitted.

Pre-distortion is well known in the art and therefore it is not explained herein in further detail.

The transmission controller controls pre-distortion functionalities such as run-time, adaptation and pre-distorter control functions, in addition to other functions in the radio unit. It is also possible to combine the two control units and place the combined control unit either in the pre-distorter or in another part of the transmitter.

The transmission controller and/or pre-distortion control functions may for instance ensure that the adaptation process stops after the upper limit for adaptation rounds has reached. After the maximum number of adaptation rounds has been reached, the pre-distortion control functions and the transmission controller may interrupt the adaptation of the pre-distorter by changing one or more messages.

The pre-distortion typically also includes means for transmission quality estimation. The estimation means may be placed partly or completely in the pre-distorter or they may be a part of the arrangement coupled with the pre-distorter.

In the following, examples of prior art transmission quality estimation methods used in 3GPP (3^{rd} Generation Partnership Project) systems are briefly clarified. The methods are explained in 3 GPP specifications in greater detail.

A error Vector Magnitude (EVM) is a measure for a difference between a reference waveform and a measured waveform. The difference is called an error vector. EVM result is defined as the square root of the ratio of a mean error vector power to a mean reference power expressed as percentages. The EVM is an indicator of the quality of modulation.

An adjacent Channel Leakage Ratio (ACRL) indicates the ratio of channel transmit power to power on one of the adjacent channels. ACRL estimation is used for measuring intermodulation distortion caused by a power amplifier.

A Spectrum Emission Mask (SEM) specifies a limit for out-of-band emissions, caused by modulation, transmitter non-linearity and/or spurious emissions. Attention should be paid to the fact that some limitations exist to the reliability of SEM estimation when the estimation is made from a feedback signal.

Other prior art options also exist for obtaining information on the transmission quality, such as determination of a direct current offset (DC-offset), signal amplitudes, Crest Factor (CF) or Complementary Cumulative Distribution Function CCDF.

FIG. 4 shows an example of a transmitter, typically placed in a network element such as a base station or in another communication device without being restricted thereto. It is obvious to a person skilled in the art that the structure of the transmitter may vary according to the current implementation.

In a transmitter, a signal is first modulated in block 400. Modulation means that a data stream modulates a carrier. A modulated signal characteristic may be frequency or phase, for example. Modulation methods are known in the art and therefore they are not explained here in greater detail.

The system in FIG. 4 being a wide-band system, the signal is spread, for example, by multiplying it with a long pseudo-random code. The spreading is carried out in block 402. If the system is a narrow-band system, no spreading block is necessary.

In DSP (Digital Signal Processing) block 404, the signal to be transmitted is processed in several ways, for instance it is encrypted and/or coded. The DSP block may also include modulation means of block 400 and spreading means of block 402, as shown by dotted-line rectangle 412. The embodiment of the data processing method described above is typically carried out in the DSP block.

Block 406 converts the signal into an analogue form. RF parts in block 408 up-convert the signal to a carrier frequency, in other words a radio frequency, either via an intermediate frequency or straight to the carrier frequency. In this example, the RF parts also comprise a power amplifier which amplifiers the signal for a radio path.

The transmitter has antenna 410. If a receiver and a transmitter use the same antenna, a duplex filter (not shown) is provided to separate transmission and reception. The antenna may be an antenna array or a single antenna.

The disclosed functionalities of the described embodiments of the data processing method can be advantageously implemented by means of software which may be located in a Digital Signal Processor. The feedback information is provided with a feedback chain. The implementation solution can also be, for instance, an ASIC (Application Specific Integrated Circuit) component. A hybrid of these different implementations is also feasible.

Even though the invention has been described above with reference to an example according to the accompanying drawings, it is clear that the invention is not restricted thereto but it can be modified in several ways within the scope of the appended claims.

1. A data processing method, the method comprising:
generating a feedback signal;
analyzing transmission quality by using the feedback signal; and
adapting a pre-distorter of a transmitter based on results of the analysis.

2. A data processing method, the method comprising:
setting a threshold for transmission quality;
generating a feedback signal;
analyzing transmission quality in a time domain and in a frequency domain by using the feedback signal; and
adapting a pre-distorter of a transmitter if the transmission quality is below the threshold.

3. The method of claim 1, further comprising setting a threshold for the transmission quality.

4. The method of claim 1, wherein said analyzing transmission quality includes analyzing the transmission quality in a time domain and in a frequency domain.

5. The method of claim 1, further comprising setting a threshold for the transmission quality and adapting the pre-distorter if the transmission quality is below the threshold.

6. The method of claim 1, further comprising interrupting the adaptation of the pre-distorter after a maximum number of adaptation rounds has been reached.

7. The method of claim 1, further comprising performing the analysis in order to track whether the pre-distorter converges in a right direction.

8. A pre-distortion device, comprising:
generating unit configured to generate a feedback signal;
analyzing unit configured to analyze transmission quality by using the feedback signal; and
adapting unit configured to adapt a pre-distorter based on results of an analysis of the analyzing unit.

9. A pre-distortion device, comprising:
generating unit configured to generate a feedback signal;
analyzing unit configured to analyze transmission quality in a time domain and in a frequency domain by using the feedback signal; and
adapting unit configured to adapt a pre-distorter if the transmission quality is below a threshold.

10. A transmitter, comprising:
generating unit configured to generate a feedback signal;
analyzing unit configured to analyze transmission quality by using the feedback signal; and
adapting unit configured to adapt a pre-distorter based on results of an analysis of the analyzing unit.

11. A transmitter, comprising:
generating unit configured to generate a feedback signal;
analyzing unit configured to analyze transmission quality in a time domain and in a frequency domain by using the feedback signal; and
adapting unit configured to adapt a pre-distorter if the transmission quality is below a threshold.

12. The transmitter of claim 10, wherein said analyzing unit is further configured to analyze the transmission quality in a time domain and in a frequency domain.

13. The transmitter of claim 11, wherein said analyzing unit is further configured to analyze the transmission quality and said adapting unit is further configured to adapt the pre-distorter if the transmission quality is below a pre-determined threshold.

14. The transmitter of claim 11, further comprising interrupting unit configured to interrupt the adaptation of the pre-distorter after a maximum number of adaptation rounds has been reached.

15. The transmitter of claim 11, further comprising performing unit configured to perform the analysis in order to track whether the pre-distorter converges in a right direction.

16. A network element, comprising:
generating unit configured to generate a feedback signal;
analyzing unit configured to analyze transmission quality by using the feedback signal; and
adapting unit configured to adapt a pre-distorter based on results of an analysis of the analyzing unit.

17. A network element, comprising:
generating unit configured to generate a feedback signal;
analyzing unit configured to analyze transmission quality in a time domain and in a frequency domain by using the feedback signal; and
adapting unit configure to adapt a pre-distorter if the transmission quality is below a threshold.

18. The network element of claim 16, wherein said analyzing unit is further configured to analyze the transmission quality in a time domain and in a frequency domain.

19. The network element of claim 17, wherein said analyzing unit is further configured to analyze the transmission quality and said adapting unit is further configured to adapt the pre-distorter if the transmission quality is below a pre-determined threshold.

20. The network element of claim 17, further comprising interrupting unit configured to interrupt the adaptation of the pre-distorter after a maximum number of adaptation rounds has been reached.

21. The network element of claim 17, further comprising performing unit configured to perform the analysis for tracking whether the pre-distorter converges to the right direction.

22. A base station, comprising:
generating unit configured to generate a feedback signal;
analyzing unit configured to analyze transmission quality by using the feedback signal; and
adapting unit configured to adapt a pre-distorter based on results of an analysis of the analyzing unit.

23. A base station, comprising:
generating unit configured to generate a feedback signal;
analyzing unit configured to analyze transmission quality in a time domain and in a frequency domain by using the feedback signal; and
adapting unit configured to adapt a pre-distorter if the transmission quality is below a threshold.

24. A pre-distortion device configured to:
generate a feedback signal;
analyze transmission quality by using the feedback signal; and
adapt a pre-distorter based on results of an analysis of the transmission quality.

25. A pre-distortion device configured to:
generate a feedback signal;
analyze transmission quality in a time domain and in a frequency domain by using the feedback signal; and
adapt a pre-distorter if the transmission quality is below a threshold.

26. A transmitter configured to:
generate a feedback signal;
analyze transmission quality by using the feedback signal; and
adapt a pre-distorter based on results of an analysis of the transmission quality.

27. A transmitter configured to:
generate a feedback signal;
analyze transmission quality in a time domain and in a frequency domain by using the feedback signal; and
adapt a pre-distorter if the transmission quality is below a threshold.

28. A network element configured to:
generate a feedback signal;
analyze transmission quality by using the feedback signal; and
adapt a pre-distorter based on results of an analysis of the transmission quality.

29. A network element configured to:
generate a feedback signal;
analyze transmission quality in a time domain and in a frequency domain by using the feedback signal; and
adapt a pre-distorter if the transmission quality is below a threshold.

30. A base station configured to:
generate a feedback signal;
analyze transmission quality by using the feedback signal; and
adapt the pre-distorter based on results of an analysis of the transmission quality.

31. A base station configured to:
generate a feedback signal;
analyze transmission quality in a time domain and in a frequency domain by using the feedback signal; and
adapt a pre-distorter if the transmission quality is below a threshold.
